(19) United States
(12) Patent Application Publication
(10) Pub. No.: US 2026/0024568 A1
(43) Pub. Date: Jan. 22, 2026

(54) TECHNIQUES FOR DATA ERASE AND CLEAR OPERATIONS USING MEMORY CELL REFRESH MECHANISMS

(71) Applicant: Intel Corporation, Santa Clara, CA (US)

(72) Inventors: Gurpreet Singh KALSI, Portland, OR (US); Akhilesh S. THYAGATURU, Sun City Center, FL (US); Karthik KUMAR, Chandler, AZ (US); Ajith PATCHANNA, Tumkure (IN)

(21) Appl. No.: 19/345,585

(22) Filed: Sep. 30, 2025

(51) Int. Cl. G11C 11/406; G11C 11/4096

(52) U.S. Cl. CPC G11C 11/40615; G11C 11/40622; G11C 11/4096

(57) ABSTRACT

Examples include techniques associated with data erase and clear operations using memory cell refresh mechanisms associated with volatile types of memory. The memory cell refresh mechanisms used for data erase and clear operations include manipulation of a refresh signal to cause volatile memory cells to be cleared or erased. The volatile memory cells to be identified as short-term memory cells.

### TECHNICAL FIELD

Examples described herein are generally related to techniques associated with data erase and clear operations using memory cell refresh mechanisms associated with volatile types of memory.

### BACKGROUND

Data clear and data erase operations associated with data stored to volatile types of memory such as DRAM can be important when implementing various different applications. For example, data clear and data erase operations can have a heightened importance for cloud, edge and artificial intelligence (AI) applications. For these types of applications, data clear and data erase operations need to ensure or maintain data security and/or privacy compliance and also enable efficient memory resource reuse.

### BRIEF DESCRIPTION OF THE DRAWINGS

FIG. 1 illustrates an example system with a host coupled with a memory module.

FIG. 2 illustrates an example of the host coupled with a memory die of the memory module, the memory die including refresh logic to facilitate data erase and clear operations.

FIG. 3 illustrates an example system configured to utilize short-term memory cells maintained on a memory die.

FIG. 4 illustrates an example first process flow.

FIG. 5 illustrates an example second process flow.

FIG. 6 illustrates an example sequence flow.

FIG. 7 illustrates an example logic flow.

FIG. 8 illustrates an example medium.

FIG. 9 illustrates an example first computing system in which data erase or data clear operations can be implemented.

FIG. 10 illustrates an example second computing system in which data erase or data clear operations can be implemented.

FIG. 11 illustrates an example mobile device in which data erase or data clear operations can be implemented.

FIG. 12 illustrates an example multi-node network in which data erase or data clear operations can be implemented.

### DETAILED DESCRIPTION

According to some examples, memory cell refresh mechanisms can be located at or with a memory die resident on a memory module such as, but not limited to, a dual in-line memory module (DIMM). In some examples, these memory cell refresh mechanisms can be initiated by a memory controller coupled with the memory module and/or the memory die or can be periodically triggered or applied to occur at specific time intervals in order to maintain a charge on memory cells included in volatile types of memory such as dynamic random access memory (DRAM) and ensure that data stored to these memory cells is maintained.

As described in more detail in this disclosure, memory cell refresh mechanisms can be used to implement data erase and clear operations that can potentially ensure or maintain data security and/or privacy compliance and also enable efficient memory resource reuse. In some example cloud application operating environments, data erase and clear operations can be frequently triggered during virtual machine (VM) decommissioning, storage repurposing, or container resets. In some example edge applications, data erase and clear operations can occurring during device handovers, firmware updates, or sensor data resets. In some example artificial intelligence (AI) application workflows, intermediate data may need to be cleared post-inference or post-training to free up memory and/or storage resources. While important or even essential, frequent erasure operations can impact system performance and increase power consumption. Techniques described in this disclosure seek to address possible bottlenecks associated with static and non-adaptive memory management associated with data erase and clear operations by using memory cell refresh mechanisms that can address performance bottlenecks associated with static and non-adaptive memory management in a manner that is proactive and adds to computational performance, energy efficiency, and overall system quality.

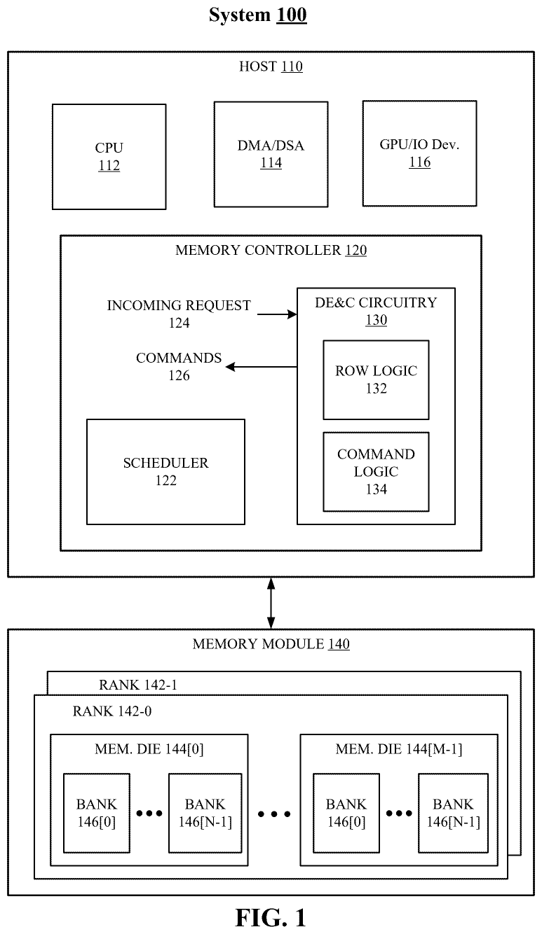

FIG. 1 illustrates an examples system 100. System 100 represents elements of a computing system with a host 110 coupled to memory resources shown in FIG. 1 as being included in a memory module 140. At least some elements of system 100, as described in greater detail below, can implement techniques for data erase and clear operations for volatile types of memory (e.g., DRAM) resident on memory module 140 using memory cell refresh mechanisms.

According to some examples, host 110 can represent a host computing platform for system 100. For these examples, as shown in FIG. 1, host 110 can include a central processing unit (CPU) 112, direct memory access (DMA)/data streaming accelerator (DSA) 114, a graphic processing unit (GPU)/input/output (IO) device 116, and a memory controller 120. CPU 112 or GPU/IO device 116 can each include one or more execution cores configured to perform operations that generate memory access requests. For example CPU 112 or GPU/IO device 116 can separately be part of a single core processor or a multicore processor, which includes separate execution units. CPU 112, DMA/DSA 114 or GPU/IO device 116 can perform operations separately or in parallel that can cause memory access requests to be sent to memory controller 120. The execution of these operations can generate changes to data that will be stored in memory, and the execution of operations can request data for execution that will request data stored in memory (e.g., maintained at memory module 140). Memory maintained at memory module 140 can represent memory for system 100, and can be or include DRAM devices or dies. Memory module 140 can maintain or house multiple separate memory devices or dies, such as multiple DRAM dies maintain on a DIMM.

According to some examples, as shown in FIG. 1, memory module 140 includes a rank 142-1 and a rank 142-2 (examples not limited to 2 ranks). Also, as shown in FIG. 1, each rank can include M memory die 144[0:M−1], collectively memory die 144. Memory die 144 can individually include N bank groups 146[0:M−1], collectively, bank groups 146. Memory die 144 can be arranged to include arrays of volatile memory cells (e.g., DRAM) to store data. Data can be stored to memory module 140 based on row address, column address, bank address, bank group, and rank. A rank is typically addressed by chip select (CS #). Memory module 140 can connect or couple with host 110 via a command bus for commands and a data bus to exchange data (not shown in FIG. 1). Memory module 140, as shown in FIG. 1 can include multiple memory devices or die that can be coupled to the data bus.

CPU 112 or GPU/IO device 116 can provide requests for data access to memory controller 120. Memory controller 120 can be arranged to manage access to memory maintained at memory module 140. Memory controller 120 receives memory access requests for CPU 112 or GPU/IO device 116 and generates commands to access memory module 140. Memory controller 120 can identify physical addresses for host addresses in the requests from CPU 112 or GPU/IO device 116.

According to some examples, memory controller 120 includes scheduler 122 to schedule commands for accesses to memory maintained at memory module 140. The commands can include activate commands, precharge commands, read commands, write commands, and other commands. In one example, memory controller 120 includes control circuitry to generate one or more commands to indicate addresses for at least some of banks 146 for use of a memory refresh mechanism associated with memory cells included in banks 146. The use of the memory refresh mechanism, as described in more detail below, can be for a data erase and/or clear operation to targeted memory cells included in banks 146. The control circuitry can generate the commands for scheduling by scheduler 122.

In some examples, the control circuitry can be represented at least partially by data erase and clear (DE&C) circuitry 130. DE&C circuitry 130 can represent control circuitry within memory controller 120 to, in some examples, facilitate or initiate use of a memory refresh mechanism for using in data erase and clear operations for data stored or maintained in memory dies at memory module 140. In one example, DE&C circuitry 130 can be implemented at least partially in firmware or software logic implemented on the hardware of memory controller 120.

According to some examples, as shown in FIG. 1, DE&C circuitry 130 can receive incoming request 124, which represents a request for memory access generated by CPU 112 or GPU/IO device 116. DE&C circuitry 130 can generate commands 126. Commands 126 can represent commands or instructions to indicate the addresses for a data erase and clear operation that uses memory cell refresh mechanisms at memory die 144 maintained at memory module 140. Commands 126 can represent the instructions or commands to trigger memory module 140 and/or memory die 144 to perform the data erase and clear operations and these instructions or commands can include a duration time period to maintain data in targeted short-term memory cells before actions are to be taken by logic and/or features at memory die 144 to perform the data erase and clear operations on the targeted memory cells.

In some examples, as shown in FIG. 1, DE&C circuitry 130 includes row logic 132. Row logic 132 represents logic to select a row address for a data erase and clear operation. Row logic 132 can select the address to provide to logic of a targeted memory die 144 (not shown in FIG. 1) maintained on or at memory module 140 through commands 126 via scheduler 122. In one example, row logic 132 generates addresses per bank 146 of a given memory die 144. Command logic 134 represents logic to generate commands 126.

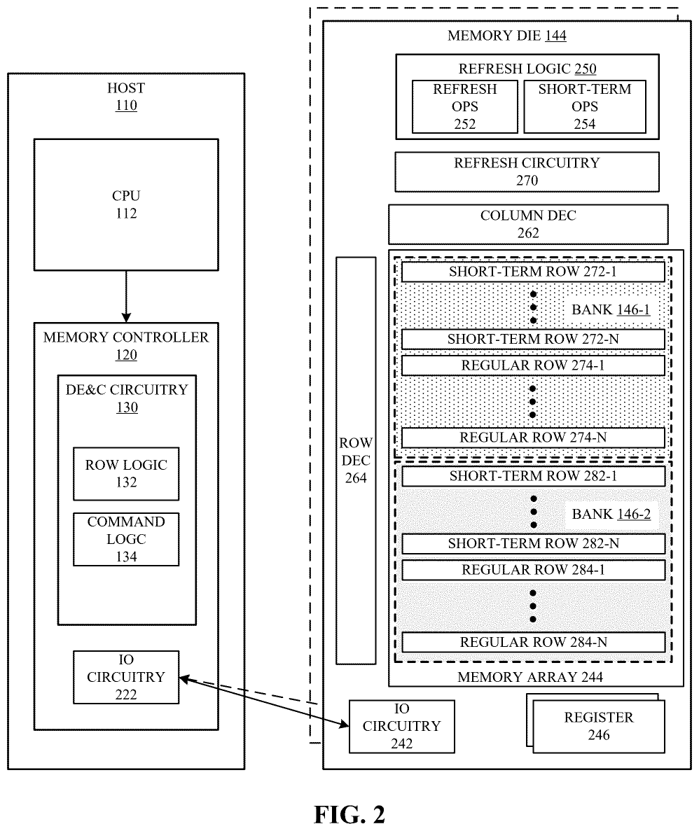

FIG. 2 illustrates an of host 110 of system 100 coupled with memory die 144 maintained on memory module 140 as shown in FIG. 1. According to some examples, as shown in FIG. 2, memory die 144 can couple to memory controller 120 via IO circuitry 242 through IO circuitry 222 of memory controller 120. Memory die 144 can include any type of memory technology that has adjacent rows of memory cells included in memory array 244, where data is accessible via a wordline or the equivalent. In one example, the memory cells included in memory array 244 may be DRAM memory cells. In some examples, memory controller 120 couples with multiple memory die 144.

Memory controller 120, as shown in FIG. 2, is part of host 110. In some examples, memory controller 120 can be an integrated memory controller of CPU 112 or of a GPU (e.g., GPU/IO device 116), which is part of the CPU or GPU die. In some examples, memory controller can be a discrete component coupled to the CPU or GPU die. While shown as a CPU, alternatively, CPU 212 can be a GPU, an accelerator processor, or other processing component.

In some examples, as shown in FIG. 2, memory die 144 includes memory array 244, which represents an array of memory cells or storage cells. A memory cell stores a bit of data, or multiple bits for a multilevel cell. Memory array 244 includes a representation of specific rows of memory array 244 can be configured to be short-term memory rows or regular rows. For these examples, portions of one or more banks of memory die 144 such as short-term rows 272-1 to 272-N of bank 146-1 and short-term rows 282-1 to 282-N of bank 146-2 can be selected for use in programmable data erase and clear operations that can include manipulation of refresh mechanisms for data maintained in short-term rows 272-1 to 272-N or 282-1 to 282-N. Meanwhile regular rows 274-1 to 274-N or 284-1 to 284-N can be selected for normal or regular operations that do not include manipulation of refresh mechanisms/signals for data maintained in these rows. As described in various examples below, memory cells included in short-term memory rows such as short-term rows 272-1 to 272-N or 282-1 to 282-N can be identified as short-term memory cells or a short-term memory region that can have a controlled data lifespan or a controlled data erasure via assertion or non-assertion of a refresh signal generated by refresh circuitry 270. The controlled data lifespan or controlled data erasure can be governed by a refresh logic 250. For example, refresh operations (Ops) 252 of refresh logic 250 can govern the assertion or non-assertion of the refresh signal generated by refresh circuitry 270 to targeted rows included in short-term rows 272-1 to 272-N or 282-1 to 282-N. Also, short-term Ops 254 of refresh logic 250 can govern the controlled data lifespan of targeted rows included in short-term rows 272-1 to 272-N or 282-1 to 282-N. In one example, at least a portion of refresh logic 250 is implemented as part of an internal controller or control logic on memory die 144 (not shown in FIG. 2).

For purposes of example, memory array 244 shows bank 146-1 and bank 146-2. It will be understood that memory array 244 can include more than two banks and the additional banks may or may not include short-term memory rows. In general, a bank or a sub-bank of memory includes memory cells that are addressable separately from memory cells of another bank or sub-bank.

According to some examples, memory die 144 includes a column decoder (DEC) 262 which represents circuitry to apply charge to a column based on an access command. In some examples, column DEC 262 can select a column in response to a column address strobe (CAS) command. Memory die 144 also includes a row decoder (DEC) 264 which represents circuitry to apply selection voltages to rows based on a memory access command. In some examples, row DEC 264 can select a row in response to a row address strobe (RAS) command.

According to some examples, IO circuitry 222 represents a hardware interface or circuitry of memory controller 120 to connect to memory die 144 and/or memory module 140. IO circuitry 222 can include pins, pads, signal lines, drivers, receivers, or other hardware, or a combination of hardware components. IO circuitry 222 can be controlled by control logic that configures and manages termination and driver components. IO circuitry 242 represents IO circuitry on memory die 144. Memory die 144 can interface with memory controller 120 via IO circuitry 242 of memory die 144 and IO circuitry 222 of memory controller 120. IO circuitry 222 and IO circuitry 242 can be configured to provide interface hardware to couple to a data bus that interconnects memory controller 120 either directly with memory die 144 or through IO circuitry of memory module 140 (not shown in FIG. 2).

In some examples, as shown in FIG. 2, memory die 144 includes register 246, which represents one or more registers or storage locations to store configuration information or values related to the operation of memory die 144. In some examples, register 246 can include one or more mode registers. In some examples, register 246 can include configuration information to control at least some operations of memory die 144 to include, but not limited to, implementation of data erase and clear operations using memory cell refresh mechanisms governed by refresh logic 250.

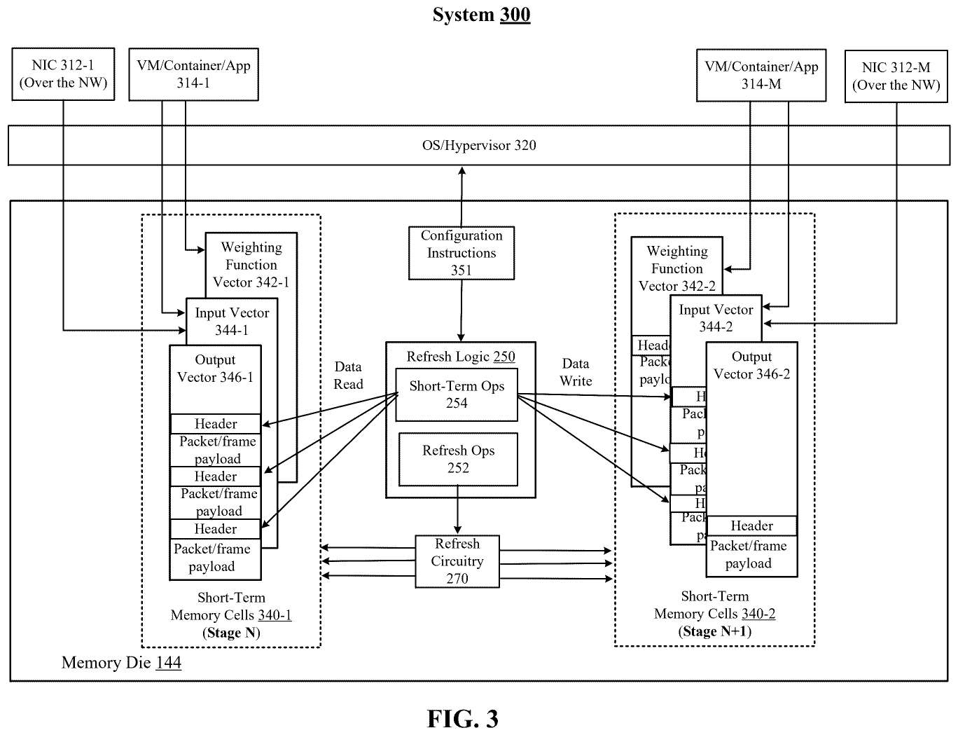

FIG. 3 illustrates an example system 300. According to some examples, system 300 can illustrate utilization of short-term memory cells 340-1 included on memory die 144 by hardware or software components of system 300. For these examples, system 300 depicts an integration at memory die 144 of programmable data erasure by refresh logic 250 of short-term memory cells 340-1 and 340-2. Refresh logic 250, for example, can be programmed or configured based on configuration instructions 351. Configuration instructions 351 can be based on specialized instructions (e.g., instruction set architecture (ISA) instructions) executed by execution units such as CPU 112, DMA/DSA 114 or GPU/IO device 116 to control and/or configure refresh logic 250. In some examples, configuration instructions 351 can be maintained in register 246 (shown in FIG. 2) and refresh logic 250 can access register 246 to obtain configuration instructions 351.

According to some examples, VMs, containers or applications (Apps) can initiate memory operations for storing data to short-term memory cells 340-1 and 340-2 via ISA instructions routed through an operating system (OS) or hypervisor 320. The ISA instructions can cause execution units such as CPU 112, DMA/DSA 114 or GPU/IO device 116 or memory controller 120 to provide configuration instructions 351 to configure or program refresh logic 250 for those initiated memory operations. For example, VM/Container/App 314-1 or 314-2 can initiate the memory operations. Configuration instructions 351 can include information to configure short-term Ops 254 and refresh Ops 252 of refresh logic 250. The information can include row/column addresses and retention duration for data to be stored to short-term memory cells 314-1 to 314-2 during the memory operations. This information of row/column addresses and retention duration can enable transient data to reside temporarily in short-term memory cells 314-1 to 314-2 and may eliminate a need for software-managed buffers or explicit memory wipes to erase or clear transient data stored to these short-term memory cells.

In some examples, short-term memory cells 340-1 to 340-2 maintained on memory die 144 can be arranged to store packet/frame payloads and are governed by refresh Ops 252 of refresh logic 250. Refresh Ops 252 can be tied to refresh circuitry 270. Once a retention timer associated with a retention duration for data stored to short-term memory cells 340-1 or 340-2 expires or an erase or clear trigger is received, refresh Ops 252 can cause refresh behavior by refresh circuitry 270 for retaining data in short-term memory cells 340-1 or 340-2 to be modified or manipulated to prevent data retention or restoration. Modifying or manipulating the refresh behavior to prevent data retention or restoration can allow for automatic and secure data invalidation for data stored to these short-term memory cells and can improve memory reuse, security and data throughput. Especially for in-memory processing pipelines or edge-cloud communication stacks. Overall, configuration of refresh logic 250 and short-term memory cells 340-1 to 340-2 can enhance inter process communications (e.g., between VM/Container/App 314-1 and 314-2) by offering low-latency, ephemeral, and secure shared memory regions, while reducing execution unit (e.g., CPU/GPU) load and memory bus contention.

According to some examples, refresh logic 250 can be configured to allow both interleaved data refresh across memory channels (e.g., DIMM DRAM memory channels) and programmable data erasure. Data in a system having multiple memory channels can be distributed (interleaved) across multiple memory channels and ranks to increase data bandwidth and reduce data latency. In order to enable per-channel or per-bank refresh behavior for memory cells maintained at a memory die, refresh Ops 252 of refresh logic 250 can be configured to have channel-aware refresh scheduling capabilities. Channel-aware refresh scheduling capabilities can enable independent refresh control per memory channel to allow concurrent refresh operations in an interleaved pattern. This prevents performance bottlenecks when accessing memory cells during memory refresh windows and supports non-blocking, parallel data erasure across multiple memory channels. Refresh Ops 252 can also be configured to have a refresh mode selector that can cause refresh circuitry 270 to switch between a standard refresh mode (data preserving) or a erase refresh mode (data destroying). The refresh mode selector can be set based on command flags to allow refresh Ops 252 to decide whether to amplify and restore data maintained in a memory cell or withhold restoration to let the memory cell discharge and cause data in the memory cell to be clear or erased. Refresh Ops 252 can also be configured to have a timing controller to extend or suppress or block a refresh signal for a restore phase of a refresh cycle based on an erase configuration set by configuration instructions 351. The timing controller, for example, can manage a dwell time that determines how long a short-term row included in short-term memory cells 340-1 or 340-2 can be held inactive (e.g., not refreshed) before it can be considered erased or cleared through charge leakage.

In some examples, system 300 can implement a stage-based pipeline integrated into short-term memory cells 340-1 to 340-2 to allow for in-place compute and memory stage progression (e.g., stage N to stage N+1) for, in some examples, an AI data processing operation. For these examples, as shown in FIG. 3, a first stage (stage N) is shown as VM/container/App 314-1 causing data associated with a weighting function vector 342-1 to be stored to a first portion of short-term memory cells 340-1. VM/container/App 314-1 and/or a physical network interface card (NIC) can cause data associated with input vector 344-1 to be stored to a second portion of short-term memory cells 340-1. A computed output based on weighting function vector 342-1 and input vector 344-1 can then be stored to a third portion of short-term memory cells 340-1. Short-term Ops 254 of refresh logic 250, as part of the in-place compute and memory stage progression, can be configured to read output vector 346-1 data stored in the third portion of short-term memory cells 340-1 and then write that data to a first portion of short-term memory cells 340-2 arranged to maintain input vector 344-2 for a second state (stage N+1). VM/container/App 314-M and/or NIC 312-M can also cause data to be stored to the first portion of short-term memory cells 340-2 to be used as input vector 344-2. Meanwhile, since the first stage has been completed, refresh Ops 252 of refresh logic 250 can cause refresh circuitry 270 to not retain (e.g., do not refresh) the data maintained in the first, second or third portions of short-term memory cells 340-1 and this can cause the data to be eventually cleared or erased due to memory cell charge leakage. Refresh Ops 252 can also cause an overwrite signal pattern to be generated, for example, by refresh circuitry 270 that targets these portions of short-term memory cells 340-1 to cause the transient data to be cleared or erased via the overwrite signal pattern (e.g., all 0's or all 1′). Regarding completion of the second stage (Stage N+1) VM/container/App 314-M can also cause data associated with weighting function vector 342-2 to be stored in a second portion of short-term memory cells 340-2. A computed output based on weighting function vector 342-2 and input vector 344-2 can then be stored to a third portion of short-term memory cells 340-2. Once output vector 346-2 is provided to a requestor or requestors of the in-place compute operation, refresh Ops 252 can cause the data maintained in the first, second and third portions of short-term memory cells 340-2 to be cleared or erased in a similar manner as mentioned above for short-term memory cells 340-1.

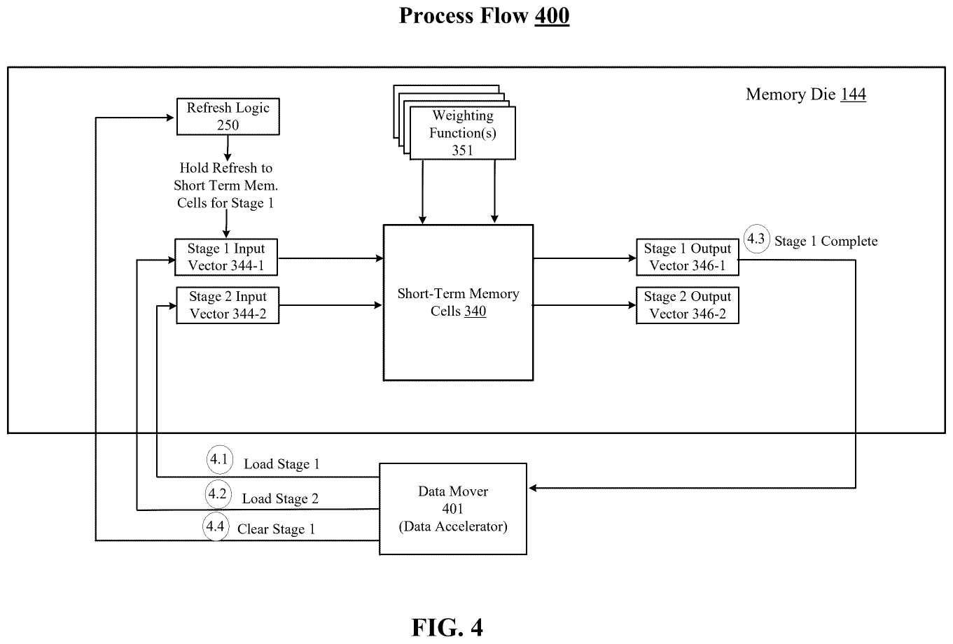

FIG. 4 illustrates an example process flow 400. In some examples, process flow 400 provides a simplified view of a processing flow for an AI data processing operation similar to what was described above for system 300. For these examples, as shown in FIG. 4, process flow 400 can be implemented by elements or components of system 100 or system 300 as shown in FIGS. 1-3 such as, but not limited to, DMA/DSA 114, memory die 144, refresh logic 250, short-term memory cells 340, weighting function(s) 342, input vectors 344, or output vectors 346.

According to some examples, at 4.1, DMA/DSA 114 can cause data associated with stage 1 input vector 344-1 to be loaded to short-term memory cells 340. Then, at 4.2, DMA/DSA 114 can cause data associated with stage 2 input vector 344-2 to be loaded to short-term memory cells 340. Then, at 4.3, once data associated with stage 1 output vector 346-1 is sent to a requestor or requestors of the AI data processing operation, an indication that stage 1 has been completed is provided to DMA/DSA 114. Then, at 4.4, DMA/DSA 114 causes refresh logic 250 to clear the data associated with stage 1 input vector 344-1 and also stage 1 output vector 346-1 from short-term memory cells 340. As mentioned above, to clear the data logic and or features of refresh logic 250 (e.g., refresh Ops 252) can be configured to cause refresh circuitry for short-term memory cells 340 to not retain (e.g., do not refresh) the stage 1 data maintained in short-term memory cells 340 to cause the stage 1 data to be cleared due to memory cell charge leakage. Logic and/or features of refresh Ops 252 can also cause an overwrite signal pattern to overwrite data stored in short-term memory cells 340 storing stage 1 data to cause this data to be cleared or erased. Once stage 2 is completed similar actions as described above for 4.3 and 4.4 can occur.

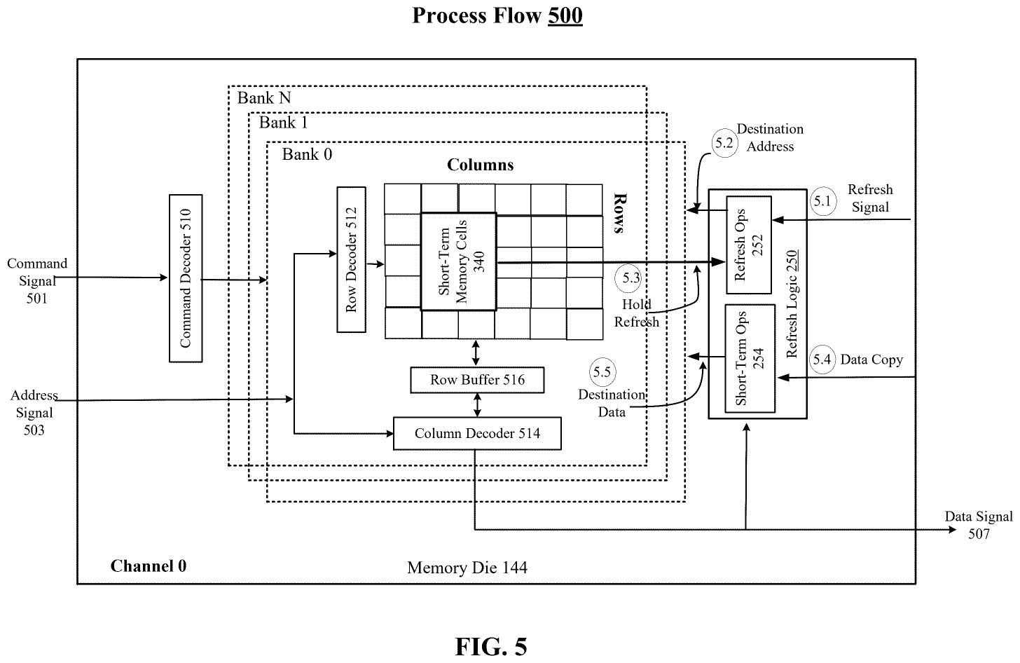

FIG. 5 illustrates an example process flow 500. In some examples, process flow 500 illustrates a process flow associated with short-term memory cells 340 integration within bank 0 from among banks 0 to N of memory die 144 for ephemeral or short-term storage of data receive over memory channel 0. For these examples, as shown in FIG. 5 and also described above for FIGS. 2-4, memory die 144 includes refresh logic 250 that can implement refresh Ops 252 and short-term Ops 254 associated with erase or clear operations to short-term memory cells 340. FIG. 5 also shows a command decoder 510 to decode commands received via command signal 501 and bank 0 specific circuitry that includes a row decoder 512, a column decoder 514 and a row buffer 516 that can be used to access short-term memory cells 340 using address information received via address signal 503. Also, a data signal 507 can represent data that can be accessed via channel 0.

According to some examples, short-term memory cells 340 can be configured as DRAM memory cells that are mapped to specialized logic and/or features of refresh logic 250 such as refresh Ops 252 that can suppress or modify a refresh restore phase targeted to the DRAM memory cells included in short-term memory cells 340. For these examples, data retention for data stored to short-term memory cells can therefore be programmatically limited. As a result of having data retention that is programmatically limited, data stored to short-term memory cells 340 can naturally clear (e.g., via cell leakage) after a configured duration or usage cycle.

In some examples, command and address decoders typically used for DRAM types of memory such as command decoder 510, row decoder 512, and column decoder 514 can be used to interact with logic and/or features of refresh logic 250. For example, short-term Ops 254 can be configured to interpret metadata originating from a CPU, DMA/DSA or GPU/IO device and route data to short-term memory cells 340 accordingly.

According to some examples, at 5.1, logic and/or features of refresh logic 250 such as refresh Ops 252 can be configured or programmed to monitor a refresh signal to determine if that refresh signal is targeted to an address that includes short-term memory cells 340.

In some examples, at 5.2, refresh Ops 252 determines that the refresh signal has a destination address that is included in short-term memory cells 340. Then, at 5.3, refresh Ops 252 cause a hold to or block the refresh of the destination address indicated in the refresh signal to cause the data stored to that address to be erased or cleared via cell charge leakage.

According to some examples, at 5.4, logic and/or features of refresh logic 250 such as short-term Ops 254 can receive an indication that a data copy operation is to cause data to be copied from one portion of short-term memory cells 340 to another portion of short-term memory cells 340 in a similar manner as described above for system 300 and process flow 400 (e.g., copy output vector data from stage 1 to input vector data for stage N+1). Then, at 5.5, short-term Ops. 254 causes the data to be copied to its new destination in short-term memory cells 340. Process flow 500 is then completed.

In some examples, design considerations for row/burst access control to memory cells included in memory die 144 can include modifying refresh logic 350 and/or refresh circuitry for memory die 144 to tag rows as short-term rows (e.g., as shown in FIG. 1) and then manage refresh signal timing of these short-term rows for data retention independently from regular or standard rows. Sence amplifiers associated with short-term rows can be tuned or configured for partial or skipped restore operations to facilitate natural decay-based erasure or clearing of short-term memory cells included in these short-term rows. Also, access policy management can include providing software application interfaces (APIs) or ISA extensions for an OS/hypervisor such as OS/hypervisor 320 show in FIG. 3 to classify data that can then be directed to short-term memory cells such as short-term memory cells 340.

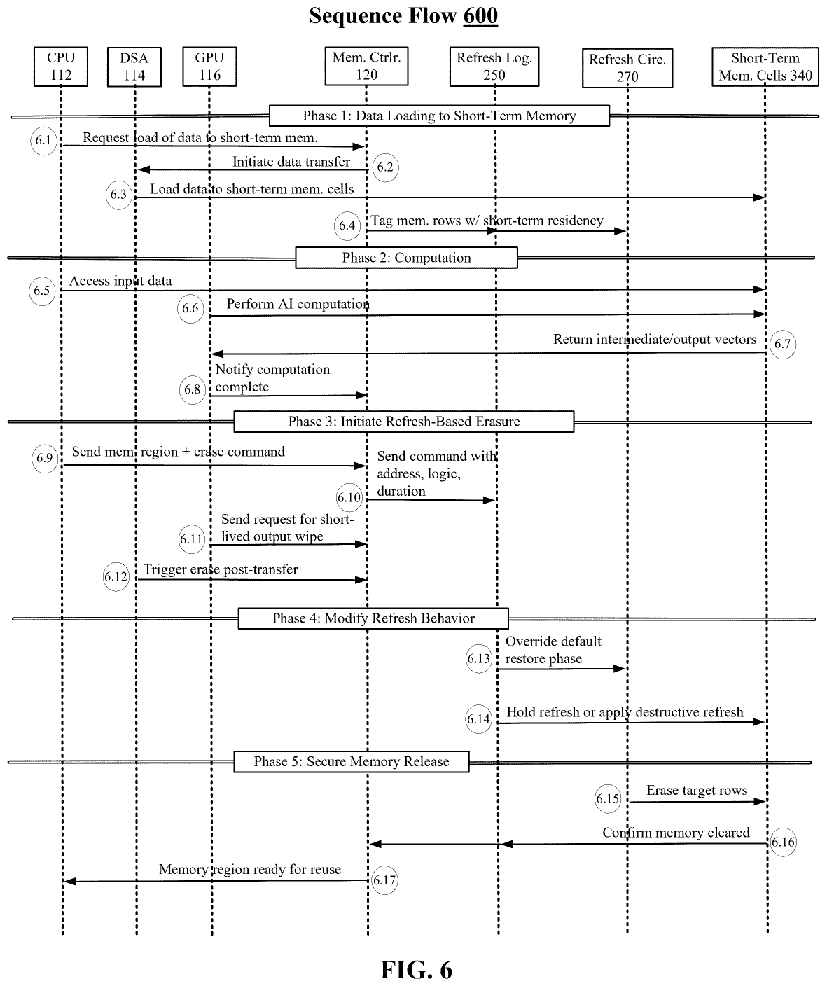

FIG. 6 illustrates an example sequence flow 600. According to some examples, as shown in FIG. 6, sequence flow 600 can be implemented by elements of system 100 such as, but not limited to, CPU 112, DMA/DSA 114, GPU 115 or memory controller 120 located on a host such as host 110. For these examples, sequence flow 600 can also be implemented by elements located at or on a memory die resident on a memory module such as memory die 144 resident on memory module 140 coupled to host 110. These elements located on the memory die can include, but are not limited to, refresh logic 250, refresh circuitry 270, or short-term memory cells 340. As shown in FIG. 6 and described more below, sequence flow 600 can be segmented into 5 phases.

In some examples, as shown in FIG. 6, phase 1 can include data loading to short-term memory. For these examples, the short-term memory can include short-term memory 340 as described above in FIGS. 3-5.

According to some examples, at 6.1, CPU 112 can place a request to memory controller 120 to load data to short-term memory. For these examples, short-term memory can be located on a memory module such as memory module 140 that includes memory die 144 configured to include short-term memory cells 340.

In some examples, at 6.2, memory controller 120 can initiate with DSA 114 a data transfer or loading of the data requested by CPU 112. For these examples, DSA 114's data streaming capabilities can be used to facilitate the loading of the data.

According to some examples, at 6.3, DSA 114 loads the data to short-term memory cells 340. Also, at 6.4, memory controller 120 tags the memory rows for which the data was loaded to by DSA 114 with a short-term residency indication. This tag, for example, can be observed by refresh logic 250 or refresh circuitry 270. Following the tagging of the memory rows, phase 1 is complete.

In some examples, as shown in FIG. 6, phase 2 can include computation. For these examples, computation can be for an AI operation that includes a stage-based pipeline integrated into short-term memory cells 340 such as described above for system 300 and process flow 400.

According to some examples, at 6.5, CPU 112 can begin the computation phase by causing each stage of the stage-based pipeline integrated in short-term memory cells 340 to access input data. For these examples, the input data can be included in the data that was loaded to short-term memory cells 340 at 6.5.

In some examples, at 6.6, GPU 116 can cause the stage-based pipeline for the AI operation to begin computations at memory die 144 using the accessed input data from short-term memory cells 340 to perform computations for each stage. Then, at 6.7, intermediate/output vectors for computations associated with the AI operation are returned to GPU 116.

According to some examples, at 6.8, GPU 116 can send an indication to memory controller 120 that the AI computations are complete. For these examples, GPU 116 has received the last output vector of the multi-stage AI operation. Phase 2 is now completed.

In some examples, as shown in FIG. 6, phase 3 is to initiate refresh-based erasure for data loaded to short-term memory cells 340. For these examples, CPU 112, DSA 114 or GPU 115 can initiate refresh-based erasure.

According to some examples, at 6.9, CPU 112 initiates refresh-based erasure of data stored to short-term memory cells 340 by sending a memory region and erase command to memory controller 120.

In some examples, at 6.10, memory controller 120 can send a refresh-based erasure command, an address for the erasure, what the logic is to do, and a duration. For these examples, the address can correspond to row and column addresses for short-term memory 340, what the logic is to do can include blocking or modifying refresh behavior, and the duration can indicate for how long the logic is to block or modify refresh behavior.

According to some examples, at 6.11, as an optional step, GPU 116 can also send a request for short-lived output wipe. This can also cause memory controller 120 to send a similar command with address, logic, duration as shown for 6.10.

In some examples, at 6.12, also as another optional or additional step, DSA 114 can initiate refresh-based erasure via a trigger erase post-transfer indication to memory controller 120. This can also cause memory controller 120 to send a similar command with address, logic, duration as shown for 6.10 after DSA 114 has completed loading data to short-term memory cells 340 as mentioned above for 6.3. Phase 3 is now completed.

According to some examples, as shown in FIG. 6, phase 4 includes modify refresh behavior.

In some examples, at 6,13, logic and/or features of refresh logic 250 such as refresh Ops 252 can be configured to cause refresh circuitry 270 to override or block a default restore phase for retaining data in short-term memory cells. Then, at 6.13, refresh logic 250 can hold or block refresh circuitry 270 from refreshing short-term memory cells 340 or can apply a destructive refresh. A hold for a duration can allow memory cell leakage to passively erase data in short-term memory cells 340. A destructive refresh can include causing a set pattern (e.g., all 1's or all 0's) to overwrite short-term memory cells 340 to actively erase or clear the data that was stored to short-term memory cells 340 prior to the destructive refresh. Phase 4 is now complete.

According to some examples, as shown in FIG. 6, phase 5 includes secure memory release.

In some examples, at 6.15, refresh circuitry 270, either through a blocked refresh or destructive refresh causes targeted rows to be erased or cleared.

According to some examples, at 6.16, controller logic at memory die 144 or refresh logic 250 can send a confirmation to memory controller 120 that short-term memory cells 340 have been erased or cleared.

In some examples, at 6.17, memory controller 120 can send an indication to CPU 112 that the memory region associated with short-term memory cells 340 is ready for reuse. Phase 5 is now complete and sequence flow 600 comes to an end.

Included herein is a logic flow representative of example methodologies for performing novel aspects of the disclosed architecture. While, for purposes of simplicity of explanation, the one or more methodologies shown herein are shown and described as a series of acts, those skilled in the art will understand and appreciate that the methodologies are not limited by the order of acts. Some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

A logic flow may be implemented in software, firmware, and/or hardware. In software and firmware examples, a logic flow can be implemented by computer executable instructions stored on at least one non-transitory computer readable medium or machine readable medium, such as an optical, magnetic or semiconductor storage. The examples are not limited in this context.

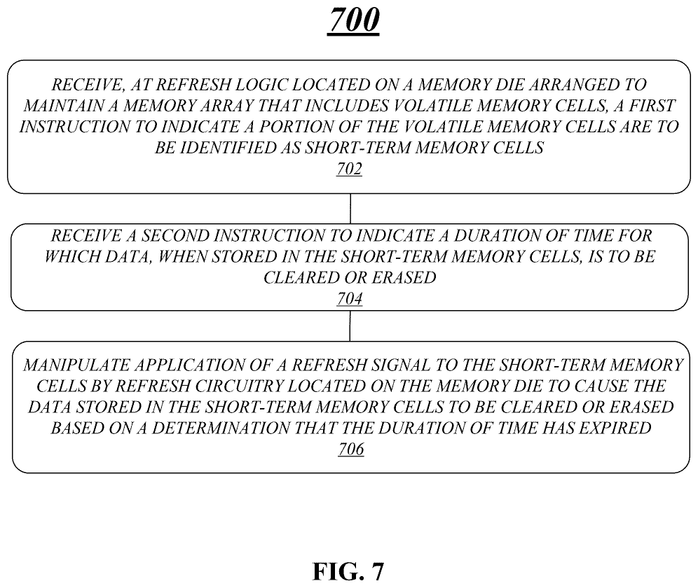

FIG. 7 illustrates an example logic flow 700. Logic flow 700 can be representative of some or all of the operations executed by one or more logic, features, or devices described herein, such as logic and/or features of refresh logic 250 located on memory die 144 arranged to maintain a memory array that include short-term memory cells 340. Logic flow 700 can represent use of memory cell refresh mechanism implemented at memory die 144 for data erase and clear operations for data stored in short-term memory cells 340.

In some examples, as shown in FIG. 7, logic flow 700 at block 702 can receive, at refresh logic located on a memory die arranged to maintain a memory array that includes volatile memory cells, a first instruction to indicate a portion of the volatile memory cells are to be identified as short-term memory cells. For these examples, refresh logic 250 can receive the first instruction that indicates short-term memory cells 340 are to be identified as short-term memory cells. The first instruction, for example, can be received from a memory controller such as memory controller 120 located at host 110 that is coupled to a memory module such as memory module 140 that includes a memory die such as memory die 144.

According to some examples, as shown in FIG. 7, logic flow 700 at block 704 can receive a second instruction to indicate a duration of time for which data, when stored in the short-term memory cells, is to be cleared or erased. For these example, refresh logic 250 can receive the second instruction. The second instruction, for example, can also be received from a memory controller such as memory controller 120.

In some examples, as shown in FIG. 7, logic flow 700 at block 706 can manipulate application of a refresh signal to the short-term memory cells by refresh circuitry located on the memory die to cause the data stored in the short-term memory cells to be cleared or erased based on a determination that the duration of time has expired. For these examples, logic and/or features of refresh logic 250 such as refresh Ops 252 can determine that duration of time indicated in the second instruction has expired and can then manipulate application of the refresh signal to cause the data stored in short-term memory cells such as short-term memory cells 340 to be cleared or erased. In one example, manipulation can include blocking the refresh signal from being applied by refresh circuitry 270 at memory die 144 to cause short-term memory cells 340 to have a charge decay that cause the data stored in the short-term memory cells 340 to be cleared or erased. In another example, manipulation can include causing refresh circuitry 270 to send an overwrite pattern signal in place of the refresh signal to cause the data stored in short-term memory cells 340 to be overwritten with the overwrite pattern signal (e.g., overwrite with all 0's or all 1's).

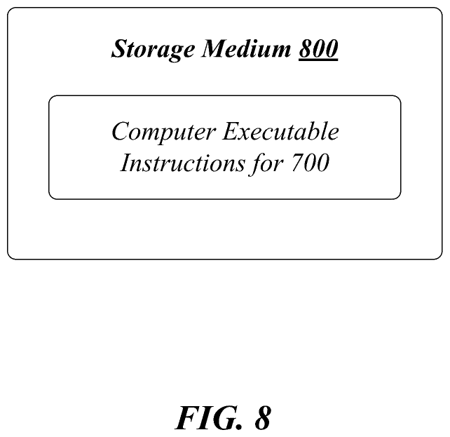

FIG. 8 illustrates an example of a storage medium. As shown in FIG. 8, the storage medium includes a storage medium 800. The storage medium 800 can comprise an article of manufacture. In some examples, storage medium 800 can include any non-transitory computer readable medium or machine readable medium, such as an optical, magnetic or semiconductor storage. Storage medium 800 can store various types of computer executable instructions, such as instructions to implement logic flow 700. Examples of a computer readable or machine readable storage medium can include any tangible media capable of storing electronic data, including volatile memory or non-volatile memory, removable or non-removable memory, erasable or non-erasable memory, writeable or re-writeable memory, and so forth. Examples of computer executable instructions can include any suitable type of code, such as source code, compiled code, interpreted code, executable code, static code, dynamic code, object-oriented code, visual code, and the like. The examples are not limited in this context.

One or more aspects of at least one example can be implemented by representative instructions stored on a machine-readable medium which represents various logic within the processor, which when read by a machine causes the machine to fabricate logic to perform the techniques described herein. Such representations, known as “IP cores” can be stored on a tangible, machine readable medium and supplied to various customers or manufacturing facilities to load into the fabrication machines that actually make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, various examples also include non-transitory, tangible machine-readable media containing instructions or containing design data, such as Hardware Description Language (HDL), which defines structures, circuits, apparatuses, processors and/or system features described herein. Such examples may also be referred to as program products.

In some cases, an instruction converter can be used to convert an instruction from a source instruction set to a target instruction set. For example, the instruction converter can translate (e.g., using static binary translation, dynamic binary translation including dynamic compilation), morph, emulate, or otherwise convert an instruction to one or more other instructions to be processed by the core. The instruction converter can be implemented in software, hardware, firmware, or a combination thereof. The instruction converter may be on processor, off processor, or part on and part off processor.

Various examples can be implemented using hardware elements, software elements, or a combination of both. In some examples, hardware elements can include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements can include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements can vary in accordance with any number of factors, such as desired computational rate, power levels, heat tolerances, processing cycle budget, input data rates, output data rates, memory resources, data bus speeds and other design or performance constraints, as desired for a given implementation.

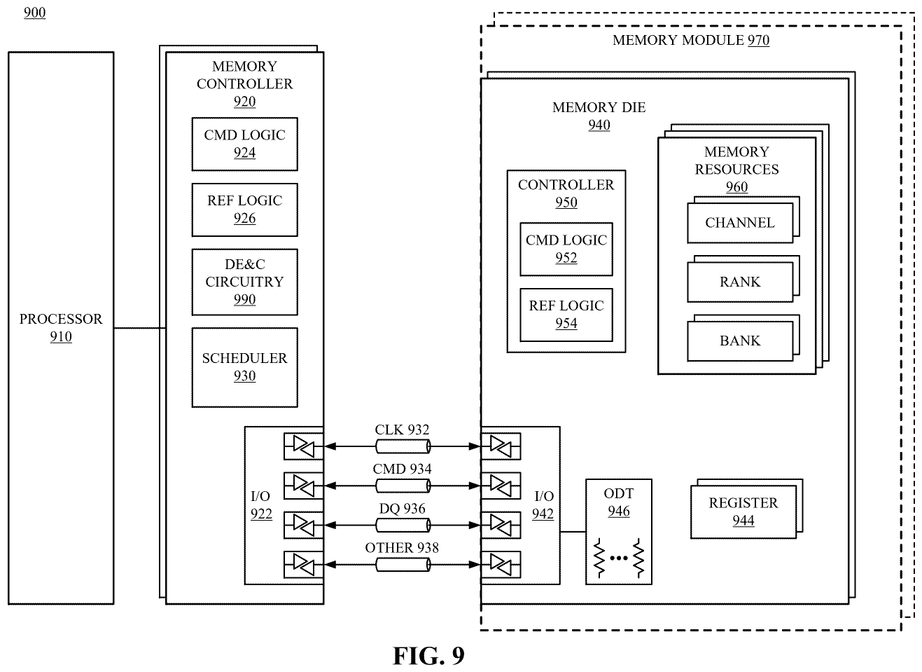

FIG. 9 illustrates an example computing system 900. Computing system 900 includes a processor and elements of a memory subsystem in a computing device. Computing system 900 represents a system in accordance with an example of system 100 or system 200.

In one example, memory controller 920 includes DE&C circuitry 990. DE&C circuitry 990 enables memory controller 920 to send instructions to implement data erase and clear operations for data stored or maintained in short-term memory maintained at memory die 940 (not shown in FIG. 9).

Processor 910 represents a processing unit of a computing platform that may execute an operating system (OS) and applications, which can collectively be referred to as the host or the user of the memory. The OS and applications execute operations that result in memory accesses. Processor 910 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. Computing system 900 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR3 (double data rate version 3), JESD79-3F, originally released by the Joint Electronic Device Engineering Council (JEDEC) in July 2012, DDR4 (DDR version 4), JESD79-4C, originally published in January 2020, DDR5 (DDR version 5), JESD79-5C, originally published in April 2024, LPDDR3 (Low Power DDR version 3), JESD209-3C, originally published in August 2015, LPDDR4 (LPDDR version 4), JESD209-4D, originally published by in June 2021, LPDDR5 (LPDDR version 5), JESD209-5C, originally published in June 2023, WIO2 (Wide Input/output version 2), JESD229-2, originally published in August 2014, HBM (High Bandwidth Memory), JESD235B, originally published in December 2018, HBM2 (HBM version 2), JESD235D, originally published in January 2020, or HBM3 (HBM version 3), JESD238A, originally published in January 2023, or other memory technologies or combinations of memory technologies, as well as technologies based on derivatives or extensions of such above-mentioned specifications.

Memory controller 920 represents one or more memory controller circuits or devices for computing system 900. Memory controller 920 represents control logic that generates memory access commands in response to the execution of operations by processor 910. Memory controller 920 accesses one or more memory devices 940. Memory devices 940 can be DRAM devices in accordance with any referred to above. In one example, memory devices 940 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 920 manages a separate memory channel, although computing system 900 can be configured to have multiple channels managed by a single controller, or to have multiple controllers on a single channel. In one example, memory controller 920 is part of processor 910, such as logic implemented on the same die or implemented in the same package space as the processor.

Memory controller 920 includes input/output (I/O) interface logic 922 to couple to a memory bus, such as a memory channel as referred to above. I/O interface logic 922 (as well as I/O interface logic 942 of memory device 940) can include pins, pads, connectors, signal lines, traces, or wires, or other hardware to connect the devices, or a combination of these. I/O interface logic 922 can include a hardware interface. As illustrated, I/O interface logic 922 includes at least drivers/transceivers for signal lines. Commonly, wires within an integrated circuit interface couple with a pad, pin, or connector to interface signal lines or traces or other wires between devices. I/O interface logic 922 can include drivers, receivers, transceivers, or termination, or other circuitry or combinations of circuitry to exchange signals on the signal lines between the devices. The exchange of signals includes at least one of transmit or receive. While shown as coupling I/O interface logic 922 from memory controller 920 to I/O interface logic 942 of memory device 940, it will be understood that in an implementation of computing system 900 where groups of memory devices 940 are accessed in parallel, multiple memory devices can include I/O interfaces to the same interface of memory controller 920. In an implementation of computing system 900 including one or more memory modules 970, I/O interface logic 942 can include interface hardware of the memory module in addition to interface hardware on the memory device itself. Other memory controllers 920 will include separate interfaces to other memory devices 940.

The bus between memory controller 920 and memory devices 940 can be implemented as multiple signal lines coupling memory controller 920 to memory devices 940. The bus may typically include at least clock (CLK) 932, command/address (CMD) 934, and write data (DQ) and read data (DQ) 936, and zero or more other signal lines 938. In one example, a bus or connection between memory controller 920 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, computing system 900 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 920 and memory devices 940. An example of a serial bus technology is 8B10B encoding and transmission of high-speed data with embedded clock over a single differential pair of signals in each direction. In one example, CMD 934 represents signal lines shared in parallel with multiple memory devices. In one example, multiple memory devices share encoding command signal lines of CMD 934, and each has a separate chip select (CS_n) signal line to select individual memory devices.

It will be understood that in the example of computing system 900, the bus between memory controller 920 and memory devices 940 includes a subsidiary command bus CMD 934 and a subsidiary bus to carry the write and read data, DQ 936. In one example, the data bus can include bidirectional lines for read data and for write/command data. In another example, the subsidiary bus DQ 936 can include unidirectional write signal lines for write and data from the host to memory, and can include unidirectional lines for read data from the memory to the host. In accordance with the chosen memory technology and system design, other signals 938 may accompany a bus or sub bus, such as strobe lines DQS. Based on design of computing system 900, or implementation if a design supports multiple implementations, the data bus can have more or less bandwidth per memory device 940. For example, the data bus can support memory devices that have either a x4 interface, a x8 interface, a x16 interface, or other interface. The convention “xW,” where W is an integer that refers to an interface size or width of the interface of memory device 940, which represents a number of signal lines to exchange data with memory controller 920. The interface size of the memory devices is a controlling factor on how many memory devices can be used concurrently per channel in computing system 900 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 940 and memory controller 920 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 940 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 940 represent memory resources for computing system 900. In one example, each memory device 940 is a separate memory die. In one example, each memory device 940 can interface with multiple (e.g., 2) channels per device or die. Each memory device 940 includes I/O interface logic 942, which has a bandwidth determined by the implementation of the device (e.g., x16 or x8 or some other interface bandwidth). I/O interface logic 942 enables the memory devices to interface with memory controller 920. I/O interface logic 942 can include a hardware interface, and can be in accordance with I/O interface logic 922 of memory controller, but at the memory device end. In one example, multiple memory devices 940 are connected in parallel to the same command and data buses. In another example, multiple memory devices 940 are connected in parallel to the same command bus, and are connected to different data buses. For example, computing system 900 can be configured with multiple memory devices 940 coupled in parallel, with each memory device responding to a command, and accessing memory resources 960 internal to each. For a Write operation, an individual memory device 940 can write a portion of the overall data word, and for a Read operation, an individual memory device 940 can fetch a portion of the overall data word. The remaining bits of the word will be provided or received by other memory devices in parallel.

In one example, memory devices 940 are disposed directly on a motherboard or host system platform (e.g., a PCB (printed circuit board) on which processor 910 is disposed) of a computing device. In one example, memory devices 940 can be organized into memory modules 970. In one example, memory modules 970 represent dual inline memory modules (DIMMs). In one example, memory modules 970 represent other organization of multiple memory devices to share at least a portion of access or control circuitry, which can be a separate circuit, a separate device, or a separate board from the host system platform. Memory modules 970 can include multiple memory devices 940, and the memory modules can include support for multiple separate channels to the included memory devices disposed on them. In another example, memory devices 940 may be incorporated into the same package as memory controller 920, such as by techniques such as multi-chip-module (MCM), package-on-package, through-silicon via (TSV), or other techniques or combinations. Similarly, in one example, multiple memory devices 940 may be incorporated into memory modules 970, which themselves may be incorporated into the same package as memory controller 920. It will be appreciated that for these and other implementations, memory controller 920 may be part of processor 910.

Memory devices 940 each include one or more memory arrays 960. Memory array 960 represents addressable memory locations or storage locations for data. Typically, memory array 960 is managed as rows of data, accessed via wordline (rows) and bitline (individual bits within a row) control. Memory array 960 can be organized as separate channels, ranks, and banks of memory. Channels may refer to independent control paths to storage locations within memory devices 940. Ranks may refer to common locations across multiple memory devices (e.g., same row addresses within different devices) in parallel. Banks may refer to sub-arrays of memory locations within a memory device 940. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 940 include one or more registers 944. Register 944 represents one or more storage devices or storage locations that provide configuration or settings for the operation of the memory device. In one example, register 944 can provide a storage location for memory device 940 to store data for access by memory controller 920 as part of a control or management operation. In one example, register 944 includes one or more Mode Registers. In one example, register 944 includes one or more multipurpose registers. The configuration of locations within register 944 can configure memory device 940 to operate in different “modes,” where command information can trigger different operations within memory device 940 based on the mode. Additionally or in the alternative, different modes can also trigger different operation from address information or other signal lines depending on the mode. Settings of register 944 can indicate configuration for I/O settings (e.g., timing, termination or ODT (on-die termination) 946, driver configuration, or other I/O settings).

In one example, memory device 940 includes ODT 946 as part of the interface hardware associated with I/O interface logic 942. ODT 946 can be configured as mentioned above, and provide settings for impedance to be applied to the interface to specified signal lines. In one example, ODT 946 is applied to DQ signal lines. In one example, ODT 946 is applied to command signal lines. In one example, ODT 946 is applied to address signal lines. In one example, ODT 946 can be applied to any combination of the preceding. The ODT settings can be changed based on whether a memory device is a selected target of an access operation or a non-target device. ODT 946 settings can affect the timing and reflections of signaling on the terminated lines. Careful control over ODT 946 can enable higher-speed operation with improved matching of applied impedance and loading. ODT 946 can be applied to specific signal lines of I/O interface logic 942, 922 (for example, ODT for DQ lines or ODT for CA lines), and is not necessarily applied to all signal lines.

Memory device 940 includes controller 950, which represents control logic within the memory device to control internal operations within the memory device. For example, controller 950 decodes commands sent by memory controller 920 and generates internal operations to execute or satisfy the commands. Controller 950 can be referred to as an internal controller, and is separate from memory controller 920 of the host. Controller 950 can determine what mode is selected based on register 944, and configure the internal execution of operations for access to memory resources 960 or other operations based on the selected mode. Controller 950 generates control signals to control the routing of bits within memory device 940 to provide a proper interface for the selected mode and direct a command to the proper memory locations or addresses. Controller 950 includes command logic 952, which can decode command encoding received on command and address signal lines. Thus, command logic 952 can be or include a command decoder. With command logic 952, memory device can identify commands and generate internal operations to execute requested commands.

Referring again to memory controller 920, memory controller 920 includes command (CMD) logic 924, which represents logic or circuitry to generate commands to send to memory devices 940. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 940, memory controller 920 can issue commands via I/O 922 interface logic to cause memory device 940 to execute the commands. In one example, controller 950 of memory device 940 receives and decodes command and address information received via I/O interface logic 942 from memory controller 920. Based on the received command and address information, controller 950 can control the timing of operations of the logic and circuitry within memory device 940 to execute the commands. Controller 950 is responsible for compliance with standards or specifications within memory device 940, such as timing and signaling requirements. Memory controller 920 can implement compliance with standards or specifications by access scheduling and control.

Memory controller 920 includes scheduler 930, which represents logic or circuitry to generate and order transactions to send to memory device 940. From one perspective, the primary function of memory controller 920 could be said to schedule memory access and other transactions to memory device 940. Such scheduling can include generating the transactions themselves to implement the requests for data by processor 910 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 920 typically includes logic such as scheduler 930 to allow selection and ordering of transactions to improve performance of computing system 900. Thus, memory controller 920 can select which of the outstanding transactions should be sent to memory device 940 in which order, which is typically achieved with logic much more complex that a simple first-in first-out algorithm. Memory controller 920 manages the transmission of the transactions to memory device 940, and manages the timing associated with the transaction. In one example, transactions have deterministic timing, which can be managed by memory controller 920 and used in determining how to schedule the transactions with scheduler 930.

In one example, memory controller 920 includes refresh (REF) logic 926. Refresh logic 926 can be used for memory resources that are volatile and need to be refreshed to retain a deterministic state. In one example, refresh logic 926 indicates a location for refresh, and a type of refresh to perform. Refresh logic 926 can trigger self-refresh within memory device 940, or execute external refreshes which can be referred to as auto refresh commands) by sending refresh commands, or a combination. In one example, controller 950 within memory device 940 includes refresh logic 954 to apply refresh within memory device 940. In one example, refresh logic 954 generates internal operations to perform refresh in accordance with an external refresh received from memory controller 920. Refresh logic 954 can determine if a refresh is directed to memory device 940, and what memory resources 960 to refresh in response to the command. In some examples, refresh signals generated by refresh logic 954 can be manipulated when targeted to short-term memory cells included in memory resources 960 based on instructions received from DE&C circuitry 990 in association with data and erase operations to the targeted short-term memory cells.

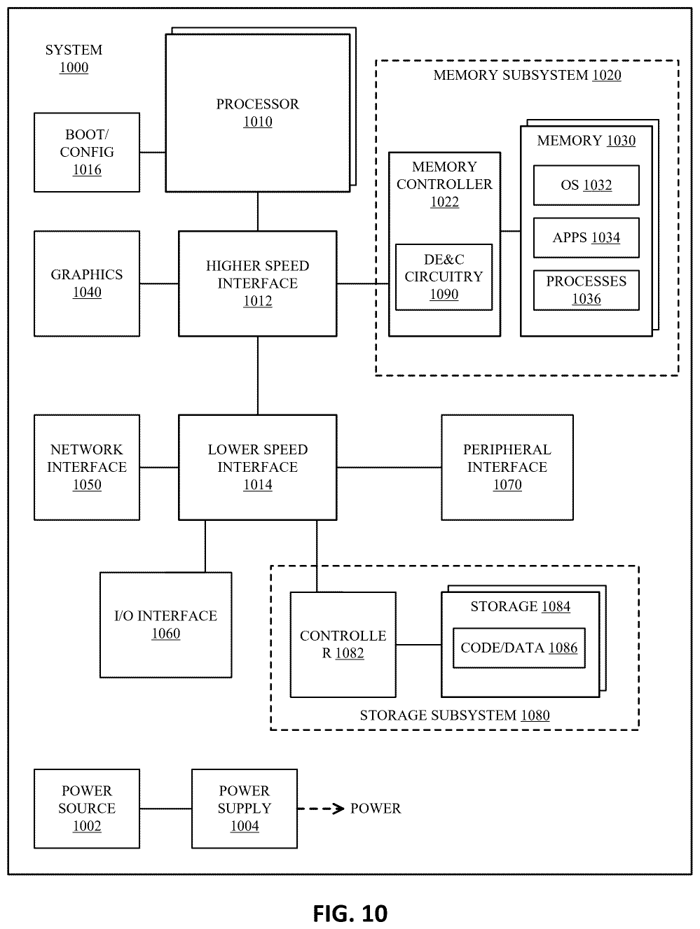

FIG. 10 illustrates an example computing system 1000. Computing system 1000 represents a computing device in accordance with any example herein, and can be a laptop computer, a desktop computer, a tablet computer, a server, a gaming or entertainment control system, embedded computing device, or other electronic device.

Computing system 1000 represents a system in accordance with an example of system 100 or system 200. In one example, memory controller 1022 includes DE&C circuitry 1090. DE&C circuitry 1090 enables memory controller 1022 to send instructions to implement data erase and clear operations for data stored or maintained in short-term memory maintained at memory 1030 of memory subsystem 1020.

Computing system 1000 includes processor 1010 can include any type of microprocessor, central processing unit (CPU), graphics processing unit (GPU), processing core, or other processing hardware, or a combination, to provide processing or execution of instructions for computing system 1000. Processor 1010 can be a host processor device. Processor 1010 controls the overall operation of computing system 1000, and can be or include, one or more programmable general-purpose or special-purpose microprocessors, digital signal processors (DSPs), programmable controllers, application specific integrated circuits (ASICs), programmable logic devices (PLDs), or a combination of such devices.

Computing system 1000 includes boot/config 1016, which represents storage to store boot code (e.g., basic input/output system (BIOS)), configuration settings, security hardware (e.g., trusted platform module (TPM)), or other system level hardware that operates outside of a host OS. Boot/config 1016 can include a nonvolatile storage device, such as read-only memory (ROM), flash memory, or other memory devices.

In one example, computing system 1000 includes interface 1012 coupled to processor 1010, which can represent a higher speed interface or a high throughput interface for system components that need higher bandwidth connections, such as memory subsystem 1020 or graphics interface components 1040. Interface 1012 represents an interface circuit, which can be a standalone component or integrated onto a processor die. Interface 1012 can be integrated as a circuit onto the processor die or integrated as a component on a system on a chip. Where present, graphics interface 1040 interfaces to graphics components for providing a visual display to a user of computing system 1000. Graphics interface 1040 can be a standalone component or integrated onto the processor die or system on a chip. In one example, graphics interface 1040 can drive a high definition (HD) display or ultra high definition (UHD) display that provides an output to a user. In one example, the display can include a touchscreen display. In one example, graphics interface 1040 generates a display based on data stored in memory 1030 or based on operations executed by processor 1010 or both.

Memory subsystem 1020 represents the main memory of computing system 1000, and provides storage for code to be executed by processor 1010, or data values to be used in executing a routine. Memory subsystem 1020 can include one or more varieties of random-access memory (RAM) such as DRAM, 3DXP (three-dimensional crosspoint), or other memory devices, or a combination of such devices. Memory 1030 stores and hosts, among other things, operating system (OS) 1032 to provide a software platform for execution of instructions in computing system 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for computing system 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010, such as integrated onto the processor die or a system on a chip.

While not specifically illustrated, it will be understood that computing system 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, computing system 1000 includes interface 1014, which can be coupled to interface 1012. Interface 1014 can be a lower speed interface than interface 1012. In one example, interface 1014 represents an interface circuit, which can include standalone components and integrated circuitry. In one example, multiple user interface components or peripheral components, or both, couple to interface 1014. Network interface 1050 provides computing system 1000 the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can exchange data with a remote device, which can include sending data stored in memory or receiving data to be stored in memory.

In one example, computing system 1000 includes one or more input/output (I/O) interface(s) 1060. I/O interface 1060 can include one or more interface components through which a user interacts with computing system 1000 (e.g., audio, alphanumeric, tactile/touch, or other interfacing). Peripheral interface 1070 can include any hardware interface not specifically mentioned above. Peripherals refer generally to devices that connect dependently to computing system 1000. A dependent connection is one where computing system 1000 provides the software platform or hardware platform or both on which operation executes, and with which a user interacts.

In one example, computing system 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, NAND, 3DXP, or optical based disks, or a combination. Storage 1084 holds code or instructions and data 1086 in a persistent state (i.e., the value is retained despite interruption of power to computing system 1000). Storage 1084 can be generically considered to be a “memory,” although memory 1030 is typically the executing or operating memory to provide instructions to processor 1010. Whereas storage 1084 is nonvolatile, memory 1030 can include volatile memory (i.e., the value or state of the data is indeterminate if power is interrupted to computing system 1000). In one example, storage subsystem 1080 includes controller 1082 to interface with storage 1084. In one example controller 1082 is a physical part of interface 1014 or processor 1010, or can include circuits or logic in both processor 1010 and interface 1014.

Power source 1002 provides power to the components of computing system 1000. More specifically, power source 1002 typically interfaces to one or multiple power supplies 1004 in computing system 1000 to provide power to the components of computing system 1000. In one example, power supply 1004 includes an AC to DC (alternating current to direct current) adapter to plug into a wall outlet. Such AC power can be renewable energy (e.g., solar power) power source 1002. In one example, power source 1002 includes a DC power source, such as an external AC to DC converter. In one example, power source 1002 or power supply 1004 includes wireless charging hardware to charge via proximity to a charging field. In one example, power source 1002 can include an internal battery or fuel cell source.

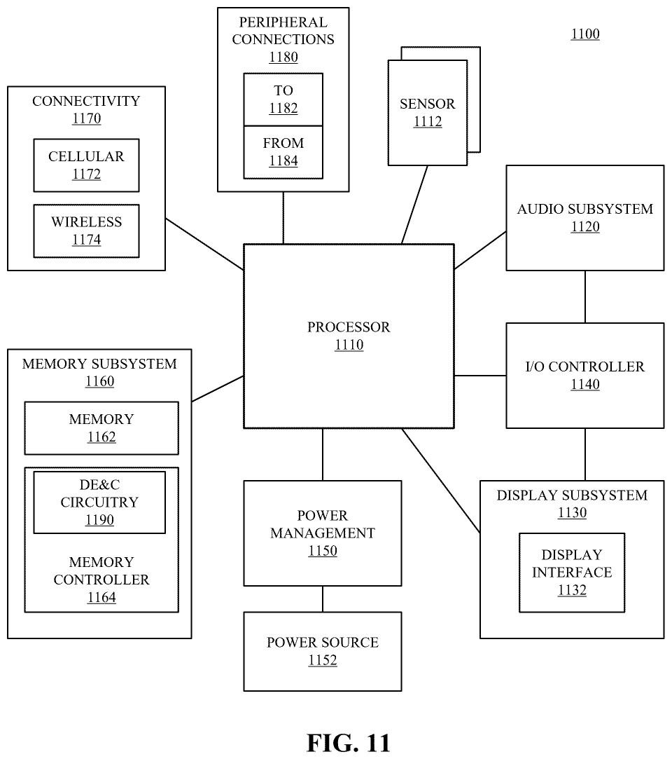

FIG. 11 illustrates an example computing system 1100. Computing system 1100 represents a mobile computing device, such as a computing tablet, a mobile phone or smartphone, wearable computing device, or other mobile device, or an embedded computing device. It will be understood that certain of the components are shown generally, and not all components of such a device are shown in computing system 1100.

Computing system 1100 represents a system in accordance with an example of system 100 or system 200. In one example, memory controller 1164 includes DE&C circuitry 1190. DE&C circuitry 1190 enables memory controller 1164 to send instructions to implement data erase and clear operations for data stored or maintained in short-term memory maintained at memory 1162 of memory subsystem 1160.

Computing system 1100 includes processor 1110, which performs the primary processing operations of computing system 1100. Processor 1110 can be a host processor device. Processor 1110 can include one or more physical devices, such as microprocessors, application processors, microcontrollers, programmable logic devices, or other processing means. The processing operations performed by processor 1110 include the execution of an operating platform or operating system on which applications and device functions are executed. The processing operations include operations related to I/O (input/output) with a human user or with other devices, operations related to power management, operations related to connecting computing system 1100 to another device, or a combination. The processing operations can also include operations related to audio I/O, display I/O, or other interfacing, or a combination. Processor 1110 can execute data stored in memory. Processor 1110 can write or edit data stored in memory.

In one example, computing system 1100 includes one or more sensors 1112. Sensors 1112 represent embedded sensors or interfaces to external sensors, or a combination. Sensors 1112 enable computing system 1100 to monitor or detect one or more conditions of an environment or a device in which computing system 1100 is implemented. Sensors 1112 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1112 can also include sensors for biometric systems such as fingerprint recognition systems, face detection or recognition systems, or other systems that detect or recognize user features. Sensors 1112 should be understood broadly, and not limiting on the many different types of sensors that could be implemented with computing system 1100. In one example, one or more sensors 1112 couples to processor 1110 via a frontend circuit integrated with processor 1110. In one example, one or more sensors 1112 couples to processor 1110 via another component of computing system 1100.

In one example, computing system 1100 includes audio subsystem 1120, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into computing system 1100, or connected to computing system 1100. In one example, a user interacts with computing system 1100 by providing audio commands that are received and processed by processor 1110.

Display subsystem 1130 represents hardware (e.g., display devices) and software components (e.g., drivers) that provide a visual display for presentation to a user. In one example, the display includes tactile components or touchscreen elements for a user to interact with the computing device. Display subsystem 1130 includes display interface 1132, which includes the particular screen or hardware device used to provide a display to a user. In one example, display interface 1132 includes logic separate from processor 1110 (such as a graphics processor) to perform at least some processing related to the display. In one example, display subsystem 1130 includes a touchscreen device that provides both output and input to a user. In one example, display subsystem 1130 includes a high definition (HD) or ultra-high definition (UHD) display that provides an output to a user. In one example, display subsystem includes or drives a touchscreen display. In one example, display subsystem 1130 generates display information based on data stored in memory or based on operations executed by processor 1110 or both.

I/O controller 1140 represents hardware devices and software components related to interaction with a user. I/O controller 1140 can operate to manage hardware that is part of audio subsystem 1120, or display subsystem 1130, or both. Additionally, I/O controller 1140 illustrates a connection point for additional devices that connect to computing system 1100 through which a user might interact with the system. For example, devices that can be attached to computing system 1100 might include microphone devices, speaker or stereo systems, video systems or other display device, keyboard or keypad devices, buttons/switches, or other I/O devices for use with specific applications such as card readers or other devices.

As mentioned above, I/O controller 1140 can interact with audio subsystem 1120 or display subsystem 1130 or both. For example, input through a microphone or other audio device can provide input or commands for one or more applications or functions of computing system 1100. Additionally, audio output can be provided instead of or in addition to display output. In another example, if display subsystem includes a touchscreen, the display device also acts as an input device, which can be at least partially managed by I/O controller 1140. There can also be additional buttons or switches on computing system 1100 to provide I/O functions managed by I/O controller 1140.

In one example, I/O controller 1140 manages devices such as accelerometers, cameras, light sensors or other environmental sensors, gyroscopes, global positioning system (GPS), or other hardware that can be included in computing system 1100, or sensors 1112. The input can be part of direct user interaction, as well as providing environmental input to the system to influence its operations (such as filtering for noise, adjusting displays for brightness detection, applying a flash for a camera, or other features).

In one example, computing system 1100 includes power management 1150 that manages battery power usage, charging of the battery, and features related to power saving operation. Power management 1150 manages power from power source 1152, which provides power to the components of computing system 1100. In one example, power source 1152 includes an AC to DC (alternating current to direct current) adapter to plug into a wall outlet. Such AC power can be renewable energy (e.g., solar power, motion based power). In one example, power source 1152 includes only DC power, which can be provided by a DC power source, such as an external AC to DC converter. In one example, power source 1152 includes wireless charging hardware to charge via proximity to a charging field. In one example, power source 1152 can include an internal battery or fuel cell source.

Memory subsystem 1160 includes memory device(s) 1162 for storing information in computing system 1100. Memory subsystem 1160 can include nonvolatile (state does not change if power to the memory device is interrupted) or volatile (state is indeterminate if power to the memory device is interrupted) memory devices, or a combination. Memory 1160 can store application data, user data, music, photos, documents, or other data, as well as system data (whether long-term or temporary) related to the execution of the applications and functions of computing system 1100. In one example, memory subsystem 1160 includes memory controller 1164 (which could also be considered part of the control of computing system 1100, and could potentially be considered part of processor 1110). Memory controller 1164 includes a scheduler to generate and issue commands to control access to memory device 1162.

Connectivity 1170 includes hardware devices (e.g., wireless or wired connectors and communication hardware, or a combination of wired and wireless hardware) and software components (e.g., drivers, protocol stacks) to enable computing system 1100 to communicate with external devices. The external device could be separate devices, such as other computing devices, wireless access points or base stations, as well as peripherals such as headsets, printers, or other devices. In one example, computing system 1100 exchanges data with an external device for storage in memory or for display on a display device. The exchanged data can include data to be stored in memory, or data already stored in memory, to read, write, or edit data.

Connectivity 1170 can include multiple different types of connectivity. To generalize, computing system 1100 is illustrated with cellular connectivity 1172 and wireless connectivity 1174. Cellular connectivity 1172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 1174 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1180 include hardware interfaces and connectors, as well as software components (e.g., drivers, protocol stacks) to make peripheral connections. It will be understood that computing system 1100 could both be a peripheral device (“to” 1182) to other computing devices, as well as have peripheral devices (“from” 1184) connected to it. Computing system 1100 commonly has a “docking” connector to connect to other computing devices for purposes such as managing (e.g., downloading, uploading, changing, synchronizing) content on computing system 1100. Additionally, a docking connector can allow computing system 1100 to connect to certain peripherals that allow computing system 1100 to control content output, for example, to audiovisual or other systems.

In addition to a proprietary docking connector or other proprietary connection hardware, computing system 1100 can make peripheral connections 1180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

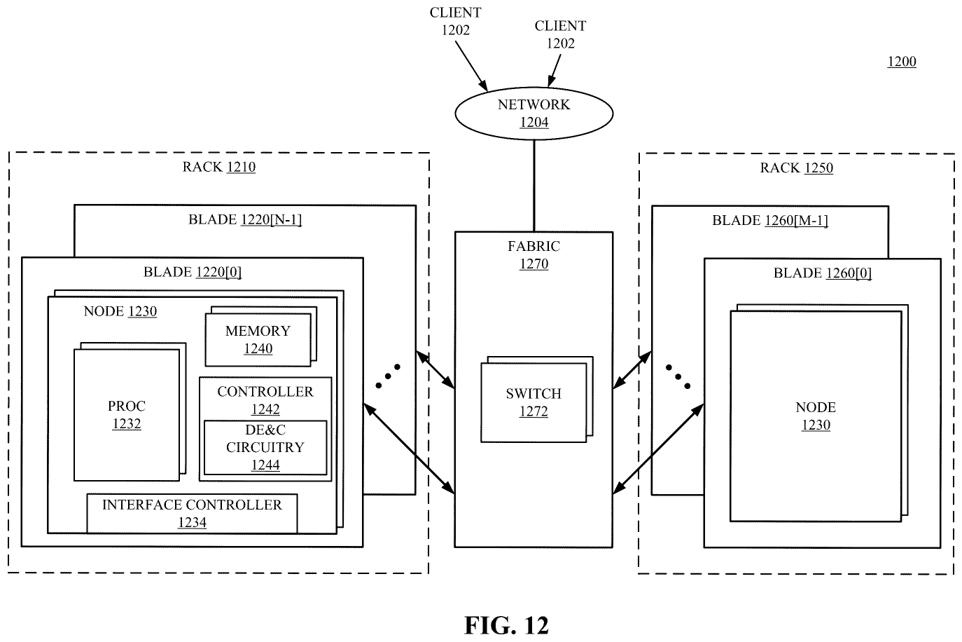

FIG. 12 illustrates an example multi-node network 1200. Multi-node network 1200 represents a network of nodes that can apply adaptive ECC. In one example, multi-node network 1200 represents a data center. In one example, multi-node network 1200 represents a server farm. In one example, multi-node network 1200 represents a data cloud or a processing cloud.

Node represents a system in accordance with an example of system 100 or system 200. Node 1230 includes memory 1240. Node 1230 includes controller 1242, which represents a memory controller to manage access to memory 1240. In one example, controller 1242 includes DE&C circuitry 1244. DE&C circuitry 1244 enables controller 1242 to send instructions to implement data erase and clear operations for data stored or maintained in short-term memory maintained at memory 124.

One or more clients 1202 make requests over network 1204 to multi-node network 1200. Network 1204 represents one or more local networks, or wide area networks, or a combination. Clients 1202 can be human or machine clients, which generate requests for the execution of operations by multi-node network 1200. Multi-node network 1200 executes applications or data computation tasks requested by clients 1202.

In one example, multi-node network 1200 includes one or more racks, which represent structural and interconnect resources to house and interconnect multiple computation nodes. In one example, rack 1210 includes multiple nodes 1230. In one example, rack 1210 hosts multiple blade components 1220. Hosting refers to providing power, structural or mechanical support, and interconnection. Blades 1220 can refer to computing resources on printed circuit boards (PCBs), where a PCB houses the hardware components for one or more nodes 1230. In one example, blades 1220 do not include a chassis or housing or other “box” other than that provided by rack 1210. In one example, blades 1220 include housing with exposed connector to connect into rack 1210. In one example, multi-node network 1200 does not include rack 1210, and each blade 1220 includes a chassis or housing that can stack or otherwise reside in close proximity to other blades and allow interconnection of nodes 1230.

Multi-node network 1200 includes fabric 1270, which represents one or more interconnectors for nodes 1230. In one example, fabric 1270 includes multiple switches 1272 or routers or other hardware to route signals among nodes 1230. Additionally, fabric 1270 can couple multi-node network 1200 to network 1204 for access by clients 1202. In addition to routing equipment, fabric 1270 can be considered to include the cables or ports or other hardware equipment to couple nodes 1230 together. In one example, fabric 1270 has one or more associated protocols to manage the routing of signals through multi-node network 1200. In one example, the protocol or protocols is at least partly dependent on the hardware equipment used in multi-node network 1200.

As illustrated, rack 1210 includes N blades 1220. In one example, in addition to rack 1210, multi-node network 1200 includes rack 1250. As illustrated, rack 1250 includes M blades 1260. M is not necessarily the same as N; thus, it will be understood that various different hardware equipment components could be used, and coupled together into multi-node network 1200 over fabric 1270. Blades 1260 can be the same or similar to blades 1220. Nodes 1230 can be any type of node and are not necessarily all the same type of node. Multi-node network 1200 is not limited to being homogenous, nor is it limited to not being homogenous.

For simplicity, only the node in blade 1220 [0] is illustrated in detail. However, other nodes in multi-node network 1200 can be the same or similar. At least some nodes 1230 are computation nodes, with processor (proc) 1232 and memory 1240. A computation node refers to a node with processing resources (e.g., one or more processors) that executes an operating system and can receive and process one or more tasks. In one example, at least some nodes 1230 are server nodes with a server as processing resources represented by processor 1232 and memory 1240. A storage server refers to a node with more storage resources than a computation node, and rather than having processors for the execution of tasks, a storage server includes processing resources to manage access to the storage nodes within the storage server.

In one example, node 1230 includes interface controller 1234, which represents logic to control access by node 1230 to fabric 1270. The logic can include hardware resources to interconnect to the physical interconnection hardware. The logic can include software or firmware logic to manage the interconnection. In one example, interface controller 1234 is or includes a host fabric interface, which can be a fabric interface in accordance with any example described herein.

Processor 1232 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1240 can be or include memory devices and a memory controller.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The following examples pertain to additional examples of technologies disclosed herein.

Example 1. An example memory device can include a memory array to include volatile memory cells. The memory device can also include refresh circuitry arranged to periodically cause data retention in the volatile memory cells via application of a refresh signal. The memory device can also include refresh logic. The refresh logic can receive a first instruction to indicate a portion of the volatile memory cells are to be identified as short-term memory cells. The refresh logic can also receive a second instruction to indicate a duration of time for which data, when stored in the short-term memory cells, is to be cleared or erased. The refresh logic can also manipulate application of the refresh signal by the refresh circuitry to cause the data stored in the short-term memory cells to be cleared or erased based on a determination that the duration of time has expired.

Example 2. The memory device of example 1, the refresh logic to manipulate application of the refresh signal can include the refresh logic to block the refresh signal from being applied to the short-term memory cells to cause the short-term memory cells to have a charge decay that causes the data stored in the short-term memory cells to be cleared or erased.

Example 3. The memory device of example 1, the refresh logic to manipulate application of the refresh signal can include the refresh logic to cause the refresh circuitry to send an overwrite pattern signal in place of the refresh signal to cause the data stored in the short-term memory cells to be overwritten with the overwrite pattern signal.

Example 4. The memory device of example 1, the data stored in the short-term memory cells can be associated with a computation that includes a stage-based pipeline integrated into the short-term memory cells.

Example 5. The memory device of example 4, the data can include input vector data, weight vector data, or output vector data for individual stages of the stage-based pipeline.

Example 6. The memory device of example 1, the volatile memory cells can be addressable based on column and row locations within the memory array. The first instruction can also include row and column address information to indicate the portion of the volatile memory cells to be identified as the short-term memory cells.

Example 7. The memory device of example 1, the first instruction and the second instruction can be received from a memory controller at a host computing platform.

Example 8. The memory device of example 7, the memory controller can send the first and second instructions responsive to a request from a central processing unit or a graphics processing unit at the host computing platform.

Example 9. The memory device of example 1, the volatile memory cells can be DRAM cells.

Example 10. An example method can include receiving, at refresh logic located on a memory die arranged to maintain a memory array that includes volatile memory cells, a first instruction to indicate a portion of the volatile memory cells are to be identified as short-term memory cells. The method can also include receiving a second instruction to indicate a duration of time for which data, when stored in the short-term memory cells, is to be cleared or erased. The method can also include manipulating application of a refresh signal to the short-term memory cells by refresh circuitry located on the memory die to cause the data stored in the short-term memory cells to be cleared or erased based on a determination that the duration of time has expired.

Example 11. The method of example 10, manipulating application of the refresh signal can include blocking the refresh signal from being applied to the short-term memory cells to cause the short-term memory cells to have a charge decay that causes the data stored in the short-term memory cells to be cleared or erased.

Example 12. The method of example 10, manipulating application of the refresh signal can include causing the refresh circuitry to send an overwrite pattern signal in place of the refresh signal to cause the data stored in the short-term memory cells to be overwritten with the overwrite pattern signal.

Example 13. The method of example 10, the data stored in the short-term memory cells can be associated with a computation that includes a stage-based pipeline integrated into the short-term memory cells.

Example 14. The method of example 13, the data can include input vector data, weight vector data, or output vector data for individual stages of the stage-based pipeline.

Example 15. The method of example 10, the volatile memory cells can be addressable based on column and row locations within the memory array, and wherein the first instruction includes row and column address information to indicate the portion of the volatile memory cells to be identified as the short-term memory cells.

Example 16. The method of example 10, the first instruction and the second instruction can be received from a memory controller at a host computing platform.

Example 17. The method of example 16, the memory controller can send the first and second instructions responsive to a request from a central processing unit or a graphics processing unit at the host computing platform.

Example 18. The method of example 10, the volatile memory cells can be DRAM cells.

Example 19. An example at least one machine readable medium can include a plurality of instructions that in response to being executed by refresh logic located on a memory die arranged to maintain a memory array that includes volatile memory cells, causes the refresh logic to receive a first instruction to indicate a portion of the volatile memory cells are to be identified as short-term memory cells. The instructions can also cause the refresh logic to receive a second instruction to indicate a duration of time for which data, when stored in the short-term memory cells, is to be cleared or erased. The instructions can also cause the refresh logic to manipulate application of a refresh signal to the short-term memory cells by refresh circuitry located on the memory die to cause the data stored in the short-term memory cells to be cleared or erased based on a determination that the duration of time has expired.

Example 20. The at least one machine readable medium of example 19, the instructions to cause the refresh logic to manipulate application of the refresh signal can include the refresh logic to block the refresh signal from being applied to the short-term memory cells to cause the short-term memory cells to have a charge decay that causes the data stored in the short-term memory cells to be cleared or erased.

Example 21. The at least one machine readable medium of example 19, the instructions to cause the refresh logic to manipulate application of the refresh signal can include the refresh logic to cause the refresh circuitry to send an overwrite pattern signal in place of the refresh signal to cause the data stored in the short-term memory cells to be overwritten with the overwrite pattern signal.

Example 22. The at least one machine readable medium of example 19, the data stored in the short-term memory cells can be associated with a computation that includes a stage-based pipeline integrated into the short-term memory cells.

Example 23. The at least one machine readable medium of example 22, the data can include input vector data, weight vector data, or output vector data for individual stages of the stage-based pipeline.

Example 24. The at least one machine readable medium of example 19, the volatile memory cells can be addressable based on column and row locations within the memory array. The first instruction can also include row and column address information to indicate the portion of the volatile memory cells to be identified as the short-term memory cells.

Example 25. The at least one machine readable medium of example 19, the first instruction and the second instruction can be received from a memory controller at a host computing platform.

Example 26. The at least one machine readable medium of example 25, the memory controller can send the first and second instructions responsive to a request from a central processing unit or a graphics processing unit at the host computing platform.

Example 27. The at least one machine readable medium of example 26, the memory controller can send the first and second instructions responsive to a request from a central processing unit or a graphics processing unit at the host computing platform.

Example 28. An example system can include a host computing platform and a memory module coupled with the host computing platform. The memory module can be arranged to maintain a plurality of memory die. The plurality of memory die can separately include a memory array to include volatile memory cells, refresh circuitry arranged to periodically cause data retention in the volatile memory cells via application of a refresh signal, and refresh logic. The refresh logic can receive a first instruction to indicate a portion of the volatile memory cells are to be identified as short-term memory cells. The refresh logic can also receive a second instruction to indicate a duration of time for which data, when stored in the short-term memory cells, is to be cleared or erased. The refresh logic can also manipulate application of the refresh signal by the refresh circuitry to cause the data stored in the short-term memory cells to be cleared or erased based on a determination that the duration of time has expired.

Example 29. The system of example 28, the refresh logic to manipulate application of the refresh signal can include the refresh logic to block the refresh signal from being applied to the short-term memory cells to cause the short-term memory cells to have a charge decay that causes the data stored in the short-term memory cells to be cleared or erased.

Example 30. The system of example 28, the refresh logic to manipulate application of the refresh signal can include the refresh logic to cause the refresh circuitry to send an overwrite pattern signal in place of the refresh signal to cause the data stored in the short-term memory cells to be overwritten with the overwrite pattern signal.

Example 31. The system of example 28, the data stored in the short-term memory cells can be associated with a computation that includes a stage-based pipeline integrated into the short-term memory cells.

Example 32. The system of example 31, the data can include input vector data, weight vector data, or output vector data for individual stages of the stage-based pipeline.

Example 33. The system of example 28, the volatile memory cells can be addressable based on column and row locations within the memory array. The first instruction can also include row and column address information to indicate the portion of the volatile memory cells to be identified as the short-term memory cells.

Example 34. The system of example 28, the first instruction and the second instruction can be received from a memory controller at the host computing platform.

Example 35. The system of example 34, the memory controller can send the first and second instructions responsive to a request from a central processing unit or a graphics processing unit at the host computing platform.

Example 36. The system of example 28, the volatile memory cells can be DRAM cells. Example 37. The system of example 28, the memory module can be a DIMM.

It is emphasized that the Abstract of the Disclosure is provided to comply with 37 C.F.R. Section 1.72 (b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A memory device comprising:
a memory array to include volatile memory cells;
refresh circuitry arranged to periodically cause data retention in the volatile memory cells via application of a refresh signal; and
refresh logic to:
receive a first instruction to indicate a portion of the volatile memory cells are to be identified as short-term memory cells;
receive a second instruction to indicate a duration of time for which data, when stored in the short-term memory cells, is to be cleared or erased; and
manipulate application of the refresh signal by the refresh circuitry to cause the data stored in the short-term memory cells to be cleared or erased based on a determination that the duration of time has expired.

2. The memory device of claim 1, wherein the refresh logic to manipulate application of the refresh signal comprises the refresh logic to block the refresh signal from being applied to the short-term memory cells to cause the short-term memory cells to have a charge decay that causes the data stored in the short-term memory cells to be cleared or erased.

3. The memory device of claim 1, wherein the refresh logic to manipulate application of the refresh signal comprises the refresh logic to cause the refresh circuitry to send an overwrite pattern signal in place of the refresh signal to cause the data stored in the short-term memory cells to be overwritten with the overwrite pattern signal.

4. The memory device of claim 1, wherein the data stored in the short-term memory cells is associated with a computation that includes a stage-based pipeline integrated into the short-term memory cells.

5. The memory device of claim 4, wherein the data comprises input vector data, weight vector data, or output vector data for individual stages of the stage-based pipeline.

6. The memory device of claim 1, wherein the volatile memory cells are addressable based on column and row locations within the memory array, and wherein the first instruction includes row and column address information to indicate the portion of the volatile memory cells to be identified as the short-term memory cells.

7. The memory device of claim 1, wherein the first instruction and the second instruction are received from a memory controller at a host computing platform.

8. The memory device of claim 7, wherein the memory controller is to send the first and second instructions responsive to a request from a central processing unit or a graphics processing unit at the host computing platform.

9. The memory device of claim 1, wherein the volatile memory cells comprise dynamic random access memory (DRAM) cells.

10. At least one machine readable medium comprising a plurality of instructions that in response to being executed by refresh logic located on a memory die arranged to maintain a memory array that includes volatile memory cells, causes the refresh logic to:
receive a first instruction to indicate a portion of the volatile memory cells are to be identified as short-term memory cells;
receive a second instruction to indicate a duration of time for which data, when stored in the short-term memory cells, is to be cleared or erased; and
manipulate application of a refresh signal to the short-term memory cells by refresh circuitry located on the memory die to cause the data stored in the short-term memory cells to be cleared or erased based on a determination that the duration of time has expired.

11. The at least one machine readable medium of claim 10, wherein to manipulate application of the refresh signal comprises the refresh logic to block the refresh signal from being applied to the short-term memory cells to cause the short-term memory cells to have a charge decay that causes the data stored in the short-term memory cells to be cleared or erased.

12. The at least one machine readable medium of claim 10, wherein to manipulate application of the refresh signal comprises the refresh logic to cause the refresh circuitry to send an overwrite pattern signal in place of the refresh signal to cause the data stored in the short-term memory cells to be overwritten with the overwrite pattern signal.

13. The at least one machine readable medium of claim 10, wherein the data stored in the short-term memory cells is associated with a computation that includes a stage-based pipeline integrated into the short-term memory cells, and wherein the data comprises input vector data, weight vector data, or output vector data for individual stages of the stage-based pipeline.

14. A system comprising:
a host computing platform; and
a memory module coupled with the host computing platform, the memory module arrange to maintain a plurality of memory die, the plurality of memory die to separately include:
a memory array to include volatile memory cells;
refresh circuitry arranged to periodically cause data retention in the volatile memory cells via application of a refresh signal; and
refresh logic to:
receive a first instruction to indicate a portion of the volatile memory cells are to be identified as short-term memory cells;
receive a second instruction to indicate a duration of time for which data, when stored in the short-term memory cells, is to be cleared or erased; and
manipulate application of the refresh signal by the refresh circuitry to cause the data stored in the short-term memory cells to be cleared or erased based on a determination that the duration of time has expired.

15. The system of claim 14, wherein the refresh logic to manipulate application of the refresh signal comprises the refresh logic to block the refresh signal from being applied to the short-term memory cells to cause the short-term memory cells to have a charge decay that causes the data stored in the short-term memory cells to be cleared or erased.

16. The system of claim 14, wherein the refresh logic to manipulate application of the refresh signal comprises the refresh logic to cause the refresh circuitry to send an overwrite pattern signal in place of the refresh signal to cause the data stored in the short-term memory cells to be overwritten with the overwrite pattern signal.

17. The system of claim 14, wherein the first instruction and the second instruction are received from a memory controller at the host computing platform.

18. The system of claim 17, wherein the memory controller is to send the first and second instructions responsive to a request from a central processing unit or a graphics processing unit at the host computing platform.

19. The system of claim 14, wherein the volatile memory cells comprise dynamic random access memory (DRAM) cells.

20. The system of claim 14, wherein the memory module comprises a dual in-line memory module (DIMM).
